(19) United States
(12) Patent Application Publication
(10) Pub. No.: US 2025/0342303 A1
(43) Pub. Date: Nov. 6, 2025

(54) ASIC DESIGN FLOW AND OBSOLESCENCE RECOVERY THROUGH OPEN-SOURCE TOOLS AND APPLICATION OF DRC RULES ON POST-SILICON LAYOUTS

(71) Applicant: Battelle Memorial Institute, Columbus, OH (US)

(72) Inventors: Andrew MCDONALD, North Canton, OH (US); Benjamin HAYDEN, Columbus, OH (US); Ryan MATTEI, Dublin, OH (US); Andrew SCHUELER, Grandview, OH (US); Adam Gakuto KIMURA, Lewis Center, OH (US)

(21) Appl. No.: 19/185,432

(22) Filed: Apr. 22, 2025

Related U.S. Application Data
(60) Provisional application No. 63/641,452, filed on May 2, 2024.

(51) Int. Cl. G06F 30/398; G06F 30/392; G06V 20/69

(52) U.S. Cl. CPC G06F 30/398; G06F 30/392; G06V 20/693

(57) ABSTRACT

In an approach to generating a DRC clean design, a method includes generating successive images of an integrated circuit, each of the successive images being associated with a different one of a plurality of layers of the integrated circuit; determining a layout of the integrated circuit in response to the successive images; collecting at least one measurement of at least one feature in the layout; and modifying the layout in response to the at least one measurement.

### CROSS-REFERENCE TO RELATED APPLICATIONS

The present application claims the benefit of the filing date of U.S. Provisional Application Ser. No. 63/641,452, filed May 2, 2024, the entire teachings of which application is hereby incorporated herein by reference.

### STATEMENT REGARDING FEDERALLY SPONSORED RESEARCH OR DEVELOPMENT

Not applicable.

### TECHNICAL FIELD

The technical field relates to application-specific integrated circuit design flow and obsolescence recovery through open-source tools and application of DRC rules on post-silicon layouts.

### BACKGROUND

Electronic circuits have been a key aspect in modernizing the world. Circuits have been made for purposes as simple as routes for delivering electricity to a light bulb, or as complex as allowing Humans to explore the universe. The increasing performance demands on these circuits has led to their form factor taking on changes over history.

While circuits are still made using wires and large physical components, many of the advanced applications take on the form of an integrated circuit (IC). Integrated circuits are similar to traditional circuits, but their components are realized in the form of active devices, such as diodes and transistors, and passive devices like resistors and capacitors. Over years of development, these devices have been able to be manufactured on a nanometer scale, allowing integrated circuits to exist as a small package containing multiple copies of circuit blocks. Integrated circuits could then be used in circuit boards allowing for a variety of circuit blocks to be connected and work together, greatly increasing the performance and functionality of circuits while minimizing cost and size. This relationship can even take place inside of the IC itself as seen with microprocessors. Microprocessors can contain thousands of linked digital circuit blocks which are able to execute program instructions and perform tasks. However, an issue with microprocessors is they are more general-purpose, meaning there could be unused functionality taking up space and power. Also, before performing the task, they will have to spend time reading program instructions which slows down the system. When size, power, and execution time are of the utmost importance, application specific integrated circuits (ASIC) are used.

As the name suggests, an ASIC is an integrated circuit made with one function in mind. While this does have the benefits as mentioned earlier, this also means that after they are produced there is no way to alter the functionality or even fix bugs. Having a specific purpose also means that production counts and demand may be lower than general purpose ICs leading to an increased cost per IC. Between the inability to fix bugs and high costs this puts an extra strain on the designer. As a result, there exists a need for an ASIC design flow to help ensure there are no errors and the IC functions as expected.

### BRIEF DESCRIPTION OF THE DRAWINGS

Reference should be made to the following detailed description which should be read in conjunction with the following figures, wherein like numerals represent like parts.

FIG. 1 is a functional block diagram illustrating a system for design flow and obsolescence recovery through open-source tools and application of DRC rules on post-silicon layouts consistent with the present disclosure.

FIG. 2 is a flow diagram depicting one illustrative example of an ASIC design flow.

FIGS. 3A and 3B are an example of a segment of register transfer level (RTL) code (FIG. 3A) and the resultant circuit components (FIG. 3B) generated from the RTL code.

FIGS. 4A and 4B are an illustrative example of equivalent cells from two different standard cell libraries.

FIGS. 5A and 5B are an illustrative example of a recovered layout (FIG. 5A) and an original (golden) layout (FIG. 5B) of an ASIC consistent with the present disclosure.

FIG. 6 is an illustrative example of a DRC rule for minimum spacing between metal traces for a given layer.

FIG. 7 is an illustrative example of measuring the distance between two metals in the opensource Klayout layout tool.

FIG. 8 is an illustrative example of applying rules to modify misshapen and unaligned shapes from the recovered layout consistent with the present disclosure.

FIG. 9 is an illustrative example of a p-channel metal-oxide semiconductor (PMOS) field-effect transistor (FET) from one process design kit (PDK).

FIG. 10 is an illustrative example of the required layers for the gate and the source/drain of a transistor in one PDK.

FIG. 11 is an illustrative example of a connectivity list to form a netlist consistent with the present disclosure.

FIG. 12 is an example diagram of a method for recovering a layout consistent with the present disclosure.

FIG. 13A illustrates a table of rule results for extracting rulesets for two separate open source PDKs, FIG. 13B illustrates a sample of the processing time required for extracting these rules from designs for each of the two open source PDKs, and FIG. 13C is an example of some DRC rules that will be extracted from the prefabricated layout, consistent with the present disclosure.

FIG. 14A is a table and FIG. 14B shows recovered versus corrected layouts for one example correction of seven layers in a recovered ASIC layout consistent with the present disclosure.

FIG. 15 shows the offset between the golden layout and the DRC corrected layout for one illustrative example consistent with the present disclosure.

FIG. 16 is an example diagram of a method for rule-driven rectilinearization of a recovered layout consistent with the present disclosure.

FIG. 17 is a flowchart diagram depicting operations for design flow and obsolescence recovery through open-source tools and application of DRC rules on post-silicon layouts, on the system of FIG. 1, consistent with the present disclosure.

FIG. 18 depicts a block diagram of components of the computing device executing the

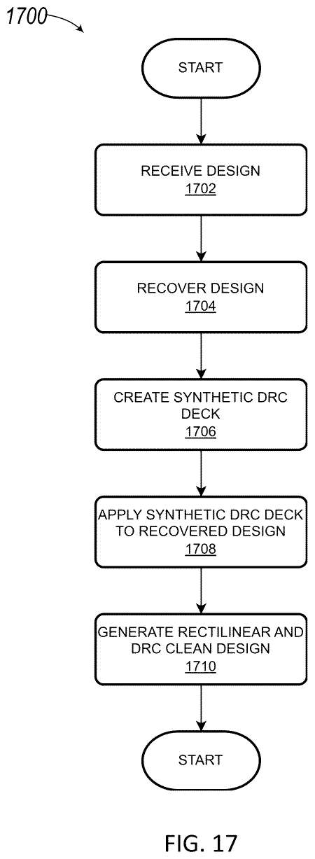

operations depicted in the flowchart of FIG. 17, consistent with the present disclosure.

### DETAILED DESCRIPTION

The present disclosure is not limited in its application to the details of construction and the arrangement of components set forth in the following description or illustrated in the drawings. The examples described herein may be capable of other embodiments and of being practiced or being carried out in various ways. Also, the phraseology and terminology used herein is for the purpose of description and should not be regarded as limiting as such may be understood by one of skill in the art. Throughout the present description, like reference characters may indicate like structure throughout the several views, and such structure need not be separately discussed. Furthermore, any particular feature(s) of a particular exemplary embodiment may be equally applied to any other exemplary embodiment(s) of this specification as suitable. In other words, features between the various exemplary embodiments described herein are interchangeable, and not exclusive.

It is not uncommon for the team designing the ASIC to be a separate entity from those manufacturing it. Not only can they be managed by a different company, but they can also be rooted in different countries. This process of designing without manufacturing is known as fabless design. Some examples of fabless IC companies are Nvidia, AMD, and Qualcomm, to name a few. While this has the benefit of having flexible locations, avoiding huge upfront costs of infrastructure to handle chip manufacturing, and allows for focus in the specialization of design work, this also creates a disconnect between handing off the design and receiving the finished product. This disconnect produces uncertainty that the chip has not been tampered with, raising the need for additional postproduction verification and validation.

Although the rigorous testing the ASIC goes through during the design flow may seem extensive, post manufacturing verification and validation are still necessary. Prior to this step, any testing that took place was all simulated using models of the hardware. While this provides useful guidance, it cannot fully replace testing the true physical device in its working environment. Releasing an ASIC that contains bugs could negatively impact the reputation of the company. And when bugs that may have been introduced during the fabless process are also security threats there could be detrimental effects on the customer as well.

As previously stated, verification and validation occur on real hardware from the foundry. This hardware is put in working conditions that match actual use cases and is tested to meet the original specifications of the first step of the ASIC design flow. This testing builds confidence in the performance of the chip, but it cannot fully guarantee the internals match those of the original design. To completely validate this matching, new techniques are needed.

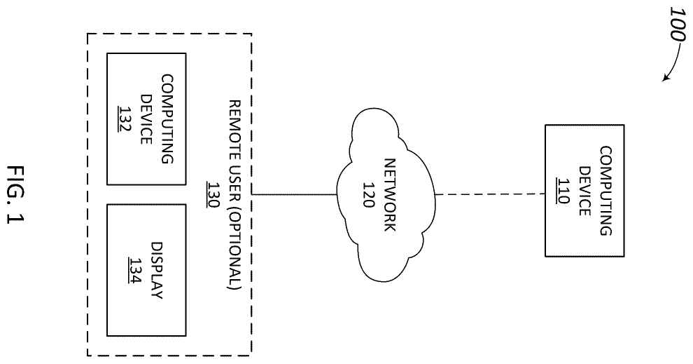

FIG. 1 is a functional block diagram illustrating a system for design flow and obsolescence recovery through open-source tools and application of DRC rules on post-silicon layouts consistent with the present disclosure. FIG. 1 provides only an illustration of one implementation and does not imply any limitations with regard to the environments in which different embodiments may be implemented. Many modifications to the depicted environment may be made by those skilled in the art without departing from the scope of the disclosure as recited by the claims.

System 100 includes computing device 110 optionally connected to network 120. Network 120 can be, for example, a telecommunications network, a local area network (LAN), a wide area network (WAN), such as the Internet, or a combination of the three, and can include wired, wireless, or fiber optic connections. In general, network 120 can be any combination of connections and protocols that will support communications between computing device 110 and other computing devices (not shown) within distributed data processing environment 100.

In an embodiment, computing device 110 can be a standalone computing device, a management server, a web server, a mobile computing device, or any other electronic device or computing system capable of receiving, sending, and processing data. In another embodiment, computing device 110 can represent a server computing system utilizing multiple computers as a server system, such as in a cloud computing environment. In yet another embodiment, computing device 110 represents a computing system utilizing clustered computers and components (e.g., database server computers, application server computers) that act as a single pool of seamless resources when accessed within distributed data processing environment 100.

In an embodiment, system 100 may include an optional remote user 130. The remote user 130 may include computing device 132 and display 134. In an embodiment, computing device 132 can be a standalone computing device, a management server, a web server, a mobile computing device, or any other electronic device or computing system capable of receiving, sending, and processing data. In another embodiment, computing device 132 can represent a server computing system utilizing multiple computers as a server system, such as in a cloud computing environment. In yet another embodiment, computing device 132 represents a computing system utilizing clustered computers and components (e.g., database server computers, application server computers) that act as a single pool of seamless resources when accessed within distributed data processing environment 100.

Display 134 provides a mechanism to display data to a user and may be, for example, a computer monitor. Display 134 can also function as a touchscreen, such as a display of a tablet computer.

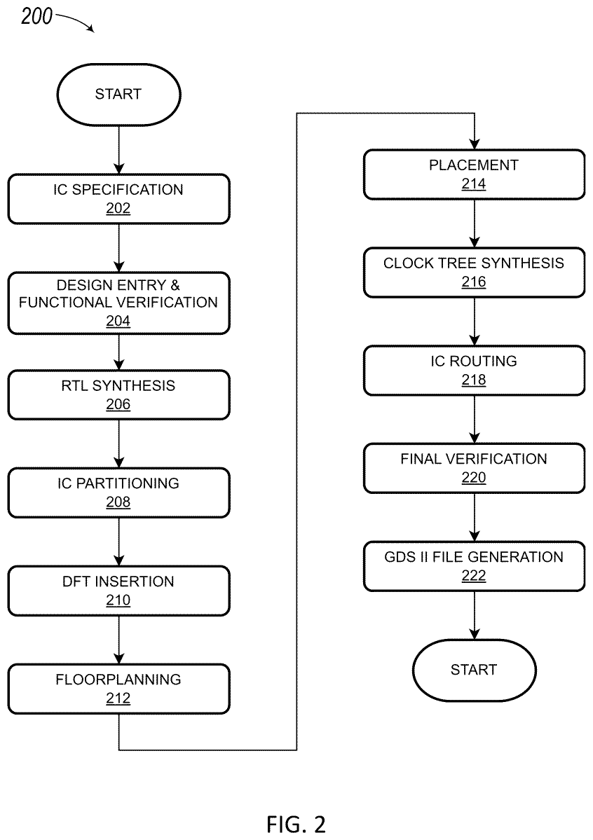

FIG. 2 is a flow diagram depicting one illustrative example of an ASIC design flow. The ASIC design flow is a time-tested cycle that has been optimized and improved with the assistance of electronic design automation (EDA) tools.

In the IC specification stage 202, like any product design, the features and functionality for the ASIC are determined. Specifications specific to circuit design like speed, area, and power consumption may also be determined in this stage. These specifications may have an immediate impact on the time sink and complexity of the design process.

Next is the design entry/functional verification stage 204. For digital design, hardware description languages such as Verilog and the Very High Speed Integrated Circuit (VHSIC) Hardware Description Language (VHDL) may be used to create register transfer level (RTL) abstractions to model the intended behavior of the circuit. Test benches may also be made to test the functionality of the RTL code. Through these tests, the RTL code can be verified to meet the requirements set in the prior stage. If any issues arise, the RTL may have to be reworked and testing may be repeated until verification passes. Exhaustive testing may take place in many sections of the design flow prior to moving on not only because of the permanent nature of ASICs described earlier, but also because of the reliance subsequent steps have on the former being concrete.

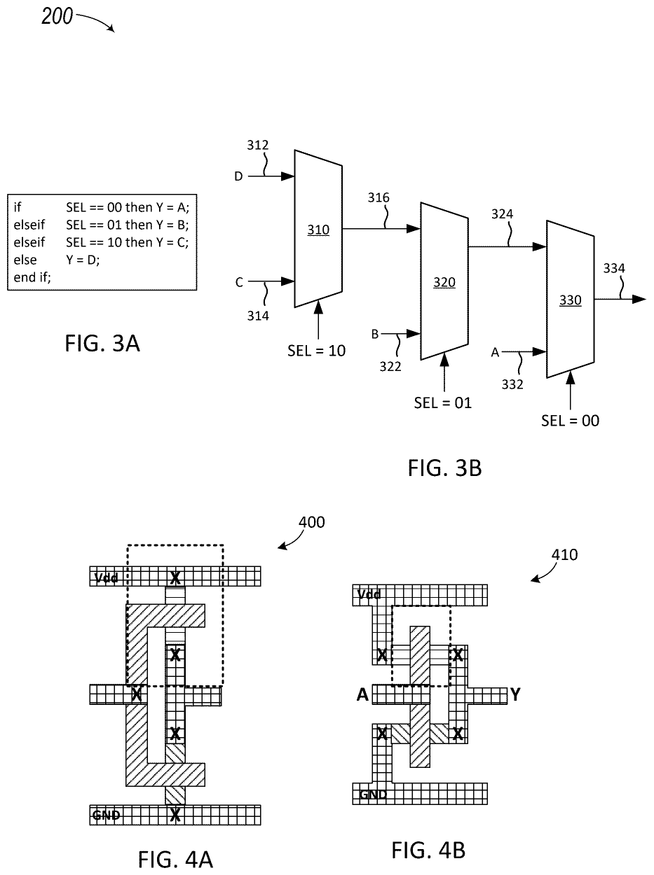

After the verification passes to a satisfactory level, the RTL synthesis stage 206 begins. During this stage, the approved RTL code gets converted or synthesized to a gate-level netlist. Essentially, this takes the higher-level hardware description language and breaks it down into a list of individual circuit components and their interconnects. For example, a conditional “if” statement in the HDL would be translated into a multiplexer with information on its input and output connections. FIGS. 3A and 3B are an example of a segment of register transfer level (RTL) code (FIG. 3A) and the resultant circuit components (FIG. 3B) generated from the RTL code.

Connecting these input and output nodes from all elements forms the net. For ASIC design, this netlist may then be used to piece together standard cells to form a physical hardware representation of the desired functionality originally described by the HDL. A standard cell is a basic logic element, such as a multiplexer as described earlier, that is used as a building block to in a circuit. Typically, an entire cell library is provided by the foundry that will be fabricating the ASIC. While two equivalent cells from different cell libraries will have the same functionality, their construction on the transistor level may vary. FIGS. 4A and 4B are an illustrative example of equivalent cells from two different standard cell libraries, which illustrates the variance among two inverter cells.

This variance alters how the cells perform in terms of the specifications from the first step in the design flow, mainly speed. So, in this step, the synthesized netlist can be better tested to meet timing constraints. Again, testing and reworking may be done in this stage until the circuit passes requirements.

Once the hardware has been decided, designers move on to the IC partitioning stage 208. Here the ASIC is broken up into sections and circuit elements are assigned to each. Assignment may be based, for example, on keeping size and power consumption low while maximizing speed.

Next is the design for test (DFT) insertion stage 210. As mentioned before, there may be no going back after fabricating the IC. Proceeding to later stages in the design flow before finding errors and having to backtrack is also very time-consuming. Pushing ASICs to achieve smaller sizes brings along more difficulties with transistor threshold voltage mismatching, size mismatching, and increased sensitivity of parasitics from connections between devices. To avoid having these problems remain hidden until later stages of the flow, particular care may be taken during designing to make it easier to test for and find any errors.

After testing, the partitions of the IC can begin to be further outlined in the floor planning stage 212 and filled in the placement stage 214. While keeping constraints in mind, blocks of connected gates from the synthesized netlist will begin to be placed on the die. Interacting blocks may be placed near each other to minimize area and ease the difficulty of the routing phase, but caution must also be taken to avoid interference between components.

After placement, clock tree synthesis 216 can begin. The clock will typically have the most connections out of any element and will consume the most power. Speed and power consumption requirements may also be determined by the frequency of the clock. In this stage, the clock is connected to all required circuit elements with special precautions to avoid synchronous mismatching or clock skew and minimize clock latency. Delays such as buffers and flops can be added in a clock tree to assist with clock matching between components or for intentional offsetting between circuit components.

Once all blocks have been placed and the clock tree has been mapped the IC routing stage 218 can begin. Routing involves connecting all circuit blocks to clock and voltage sources, input and output pins, and collaborating circuit blocks to each other in the layout. With so many circuit elements located in a tiny space, vertical layer stacks may be used to prevent undesired cross connections of metal wires. Design rules may also be followed to prevent this as well as ensure no connections will be corrupted due to deviations in the fabrication process. The path and layers chosen to make these connections also introduce additional parasitics which can alter speed and power consumption of the circuit blocks. The number of layers available and rules for placement of metals on these layers may be determined by the foundry manufacturing the IC.

Once the layout has been routed, the final verification stage 220 begins. As mentioned, the routing stage not only handled interconnections between circuit blocks, but also had design rules to abide by, and may have even introduced new parasitics. To ensure the circuit still behaves as intended, checks such as layout versus schematic (LVS) and design rule checks (DRC) may be done. Post layout simulations may also be executed in this step. Layout versus schematic deals with checking that the interconnections were done correctly. A netlist can be derived from connection points made in the layout and compared to the netlist generated for the schematic. If these netlists match, the circuit passes the LVS check. For a circuit to pass the DRC, the routing of the layout must abide by all the rules defined by the foundry. DRC checking is typically performed during the routing stage as well as the final verification stage. These rules can exist as minimum spacing between metals, minimum width of metals, and more. As mentioned, following these rules helps to ensure that the layout is actually capable of being manufactured. These rules also help prevent corruption of signals within the IC. Parasitics from layout can be approximated and used on post layout simulations to model behavior of the circuit once it has been fabricated. If the circuit still does not pass speed, power, and size specifications post layout, the routing stage must be reworked before coming back to the verification stage.

After final verification has passed, the Graphic Design System (GDS) II file generation stage 222, which is the final stage, is reached. GDSII is a file format used by the foundry for fabricating the IC. This file is a representation of the ASIC layout containing all the circuit elements and connections between them. It also contains all the layers used to make the layout possible.

Integrated circuit delayering and imaging is a destructive method that can assist in confirming the internals of hardware. This process takes advantage of the ASICs being built up using multiple layers for creating the circuits. An individual layer can be etched or delayered exposing the electrical connections hidden underneath. The exposed layer can be captured using imaging hardware before repeating the delayering process.

Once all the layers have been accounted for, these images are used to recreate a GDSII file representing the layout of the original circuit. If an IC failed during the environmental verification testing, this layout could provide insight as to what may have caused the failure.

In some embodiments, the disclosed system and method may first perform a delayering process to create a GDSII of the recovered design. Then, by knowing the DRC rules from the PDK, the system can set constraints on the recovered design that would have been applied to the original design in order to be manufactured. Molding the recovered GDSII allows for better comparison to the original golden design file when performing verification and validation (V&V).

In some embodiments, if the PDK for a design is not available, the golden design can be used to derive a set of DRC rules for the recovered design. Similarly, this derived DRC ruleset is then used to mold the recovered shapes to fit more closely to a golden shape should be and assist V&V.

Another use case for this delayering and imaging process is obsolescence recovery. A company may have a legacy IC that is still used in systems, but all schematics are lost. For maintenance and future use, knowing that the IC satisfies existing use cases, the company may want to produce more instances of the IC, or use the IC as a foundation for improved designs in order to forgo some steps of the lengthy design process. The layout derived from the imaging process can be used to recover the original circuit schematic to assist in this process.

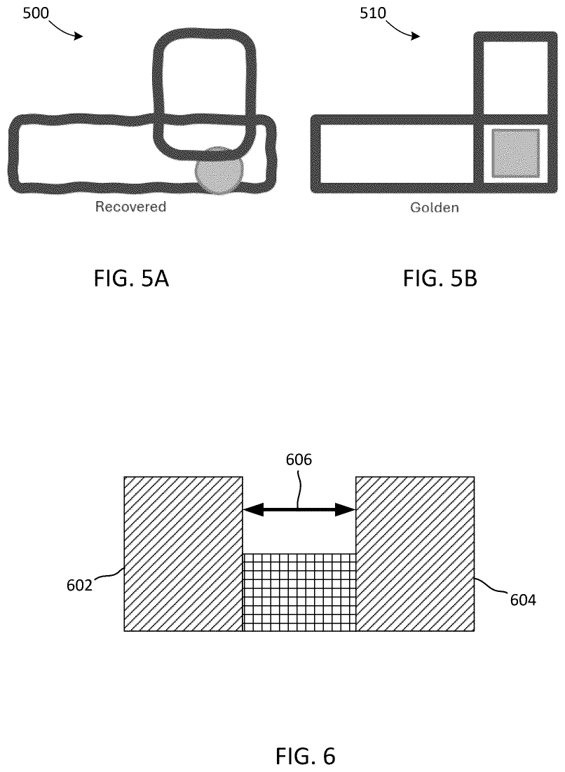

Recovered layouts are a valuable resource for verification and validation of ASICs and modernization of legacy designs. Comparison between the recovered and the originally designed (golden) layouts allows for immediate assertion of matching internals. Unfortunately, due to the nature of transistor technology shrinking in scale, the quality of these images captured by delayering an IC is not perfect. Metal connections between circuit elements can be distorted into jagged shapes and/or slightly offset from the smooth rectangles found in the originally designed layout. FIGS. 5A and 5B are an illustrative example of a recovered layout 500 (FIG. 5A) and a golden layout 510 (FIG. 5B) of an ASIC consistent with the present disclosure. Not only can this make verification against the golden layout a challenge, but it also adds immense difficulties when trying to recover legacy designs when the golden layout is lost.

When the golden layout is not available, in some embodiments consistent with the present disclosure there are provided techniques to modify the recovered layout to better represent the golden layout. During the ASIC design flow the circuit is DRC passed in order to be fabricated. The set of design rules is specific to the PDK used to create the IC. The PDK will also contain information on the layers used in a layout and feature sizes of the transistors in the circuits.

A common DRC rule is minimum spacing between metal traces for a given layer. For example, in a common opensource PDK, the minimum space between two metals on layer “metal1” is 0.140 micrometers. FIG. 6 is an illustrative example of a DRC rule for minimum spacing between metal traces for a given layer. In the example of FIG. 6, a first metal trace 602 and a second metal trace 604 are separated by a required minimum space 606.

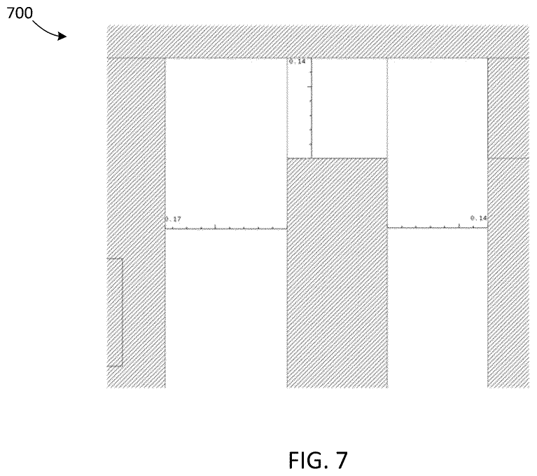

By collecting the measurement between each metal shape across an entire layer and normalizing the minimums, a new rule for minimum spacing for this layout can be created. This process can be done, for example, through an opensource GDSII viewer/editor such as Klayout. Klayout has an extensive Python Application Programming Interface (API) that provides means for automating stepping through individual shapes of a layout. FIG. 7 is an illustrative example of measuring the distance between two metals in the opensource Klayout layout tool.

This process can be repeated for additional dimensions such as minimum metal widths, minimum via enclosures, minimum channel length, and so on. Once all these derived rules are collected, a pseudo PDK may be created. Then, by comparing the pseudo PDK to a library of real PDKs, it is possible to decide the real PDK used for the design.

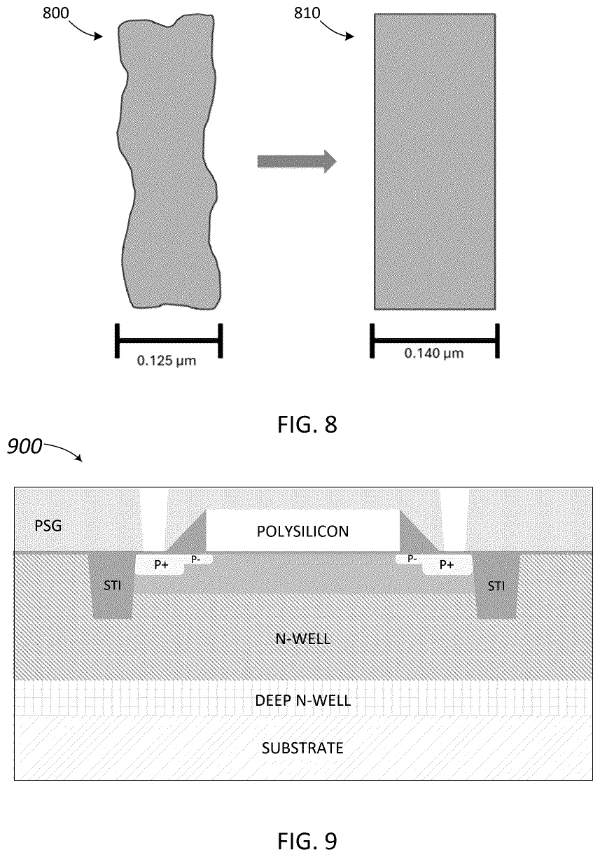

Once a PDK is determined, there will be an exhaustive list of rules that the layout must follow. This information can be used to modify the misshapen and unaligned shapes from the recovered layout to fit the defined rules. For example, for one common PDK, the width of a metal1 trace must be at least 0.140 micrometers. Therefore, any metal1 traces that do not meet that width can be expanded to the new dimension. FIG. 8 is an illustrative example of applying the rules to modify misshapen and unaligned shapes from the recovered layout.

After repeating this process for all rules and shapes, the recovered GDSII will be much more symbolic of the golden layout. This enhancement of the recovered layout will be even more accurate in cases where the golden layout was not lost. The golden layout will provide better anchor points for realignment and further assist in the smoothing of the jagged metal shapes.

Once the recovered layout mirrors the golden layout, verification by comparison becomes more accessible. Additionally, assembling the original circuit schematic is achievable.

Manually recreating the circuit schematics from legacy ASICs for obsolescence modernization is possible but extremely tedious. By utilizing layout files, and open-source tools, consistent with the present disclosure automating this process becomes an option. Again, in the digital design flow, the hardware description language is synthesized into a gate level netlist. The circuit blocks used to achieve the functionality laid out by the HDL are dependent on standard cells for a given PDK. By knowing the PDK, the PDK provides a collection of cells to search for in a layout. Unfortunately, this method immediately is of less use for ASICs involving analog design. Analog design should be hand made to account for varying transistor sizes and routing paths having intentional impacts on the circuit's operation. So, an approach that encompasses both analog and digital design should be taken.

One method that allows for both is device extraction. Device extraction is the technique of sifting through layers of the layout to find circuit components such as transistors, resistors, capacitors, and so on. A simple example of finding a transistor would be search for overlapping regions of polysilicon and diffusion layers. The PDK would provide more extensive information on layer selection, size, placement, and more for a given device. FIG. 9 is an illustrative example of a p-channel metal-oxide semiconductor (PMOS) field-effect transistor (FET) from the aforementioned common PDK. FIG. 9 is a cross section model of the PMOS FET whereas the layout would be a vertical view.

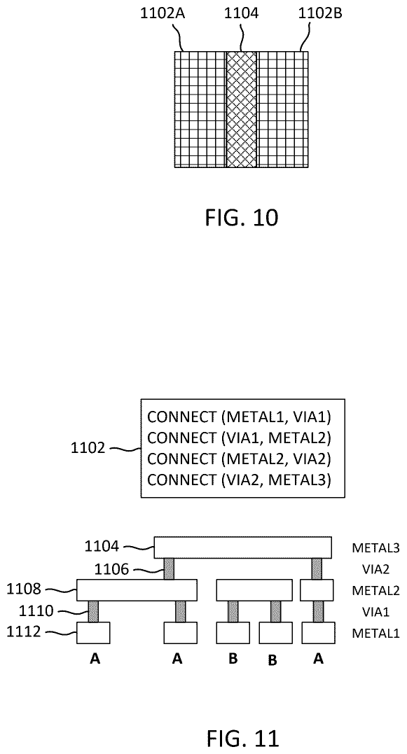

After determining the layers of the device, the next step would be finding which layers in particular are necessary for extraction. For a PMOS transistor, Klayout requires layers for the gate and the source/drain as shown in FIG. 10. In the example of FIG. 10, the gate layer 1104 is located between a first source/drain layer 1102A and a second source/drain layer 1102B. After separating the device from the rest of the layout, its connections can begin to be formed.

Once a component is found, the nodes it is connected to can be traced through a user-made connectivity list to form a netlist for each individual circuit component. This connectivity list functionality is supported by Klayout and plays off traditional LVS tools. The connectivity list will specify the path through layers a signal could take to get from one point to another. The illustrative example shown in FIG. 11 highlights a path being formed between two metals through the use of vias. After repeating this for every device, a netlist is made for the whole circuit. With this netlist, the legacy circuit can be recreated.

The netlist also provides another route for verification and validation. If the original netlist from the RTL synthesis is available, this extracted netlist can be used for comparison against the original. If the design features analog components, but the original circuit is known, opensource tools such as Xschem can be used to build the circuit and generate a netlist. From there, the derived and the generated netlists can be compared for verification.

The advancement towards ASICs was a revolutionary step for electronics. ASICs offer superior performance while maintaining a small profile when compared to other topologies. Along with these benefits come tradeoffs in sophistication of design and exorbitant costs. The likelihood for bugs to occur is higher and if they are not caught prior to production their impact is detrimental. Also, the precision required to manufacture these microscopic devices can lead to manufacturing errors after the design phase. Furthermore, design simulations cannot fully account for the true environmental application of the IC. To help mitigate chances of these bugs impacting the performance of the IC or the system a manufactured IC is utilized in, verification and validation testing is crucial. By building off existing delayering and imaging practices, a method consistent with the present disclosure can provide additional tools for post fabrication verification. The complexity of designing and validating a new ASIC increases the value of existing, successfully designed ASICs. Methods consistent with the present disclosure also provide a path for obsolescent recovery to circumvent some of the costs of the design flow.

In some embodiments a method consistent with the present disclosure may utilize a golden layout or synthetic derived DRC deck to flag and correct DRC violations during rectilinearization. During post silicon verification and validation when a layout is recovered, the resultant layout can be non-rectilinear and may not follow DRC rules. In a traditional rectilinearization flow, DRC rules are not considered therefore the resultant rectilinear layout does not closely represent the post fabricated layout. Non-rectilinear layouts cause verification and validation processes to be much harder when using traditional EDA tools. In some embodiments a method consistent with the present disclosure utilizes synthetic DRC rules derived from a golden layout (no PDK needed) or golden DRC rules from a PDK to guide the rectilinearization algorithm. This produces a layout that closely represents a pre-fabrication layout but also preserves recovered layout artifacts. When performing rectilinearization the algorithm tries to remove all points that have some slope between them so that the result only contains perfectly horizontal or vertical lines. Some embodiments consistent with the present disclosure extend the rectilinearization algorithm and add DRC “checks” to verify that the polygon it is creating does not violate DRC rules which include, but are not limited to, polygon to polygon spacing, polygon width/length, and more. This significantly reduces the risk of manual error associated with known manual processes.

Geometry of polygons are extremely important when performing some post-silicon verification and validation (V&V) methods. If the geometry of polygons are not correct, some V&V methods may produce incorrect results. Furthermore, when the design PDK is not provided for a layout, image correction methods cannot be fully trusted. Post-silicon DRC rule analysis and application consistent with the present disclosure gives the ability to generate a synthetic DRC deck from a layout that uses an unknown PDK and apply the generated synthetic deck towards polygon rectilinearization. This provides a true rule driven polygon correction method which results in a recovered layout that better represents the golden layout that was sent for tapeout. This corrected recovered layout can then be used during the V&V process and will have more trusted and accurate results.

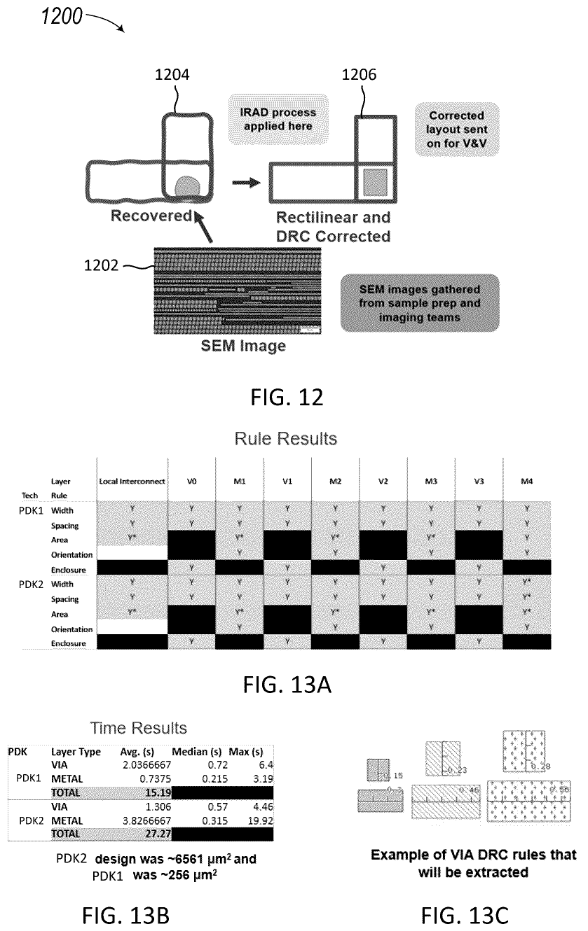

FIG. 12 is an example diagram of a method for recovering a recovered layout consistent with the present disclosure. In the example method of FIG. 12, a recovered layout 1204 is derived from a scanning electron microscope (SEM) image 1202. After the disclosed method is applied to the recovered layout 1204, the rectilinear and DRC corrected layout 1206 is created, which is then sent on for V&V.

Synthetic DRC decks are derived from the golden prefabricated layout. These synthetic decks are then applied to the recovered layout for polygon correction. This process was tested on two open source PDKs and checked with the actual values for verification. FIGS. 13A-13C are an example of a subset of DRC rules derived from two open source PDKs.

FIG. 13A illustrates a table of rule results for extracting rulesets for two separate open source PDKs. In this example, a set of DRC rules are attempted to be derived for two separate GDSII files, each lacking the original PDK. The row across the top is the different metal layers within the GDS and the first column lists commonly used DRC rules when laying out an IC during the design phase. The green ‘Y’ shows that the system was able to extract a ruleset for that category in a given layer. So, the ‘Y’ under PDK1 M1 Width means that the system could trend a minimum width requirement for that layer, and the minimum width requirement matched the actual DRC rule from the PDK. This would later be used to assist with correcting recovered shapes to form to this requirement. The ‘Y*’ means that the system did find a value, but it did not match the minimum value for that DRC rule from the PDK due to the reference design not following the minimal DRC rules.

FIG. 13B illustrates a sample of the processing time required for extracting these rules from designs for each of the two open source PDKs. The Avg. (s) is the time required to process each via layer or metal layer (median and maximum show that different via layers took longer than others) and the total time to process the whole design. There are several via layers in metal layers in a single design as illustrated by FIG. 13A.

FIG. 13C is an example of some DRC rules, in this example, three different via layers, that will be extracted from the prefabricated layout. The measurements on the vias are just examples illustrating what is meant in finding the minimum width or area in FIG. 13A.

The synthetic DRC deck of FIGS. 13A-13C is only a small subset of the most important rules that are needed for DRC driven rectilinearization.

DRC rules can only be derived if the designer selects to use that minimum rule. This step can be bypassed if a PDK is provided for the V&V work. The PDK can be given to the DRC rectilinearization process in the same way and will achieve the same results.

When deriving the DRC ruleset without knowing the PDK, the system has to assume that each layer is following the minimum width/area/spacing/etc., requirement (this assumption is reasonable because smaller is better in many cases). In reality, designers can make shapes larger than the minimum requirement (to an extent). If a layer does not follow the minimum, the system can still get a value for a “minimum” width on that layer but it may not be the true minimum that the layer is designed to and therefore may not match the minimum DRC ruleset from the PDK.

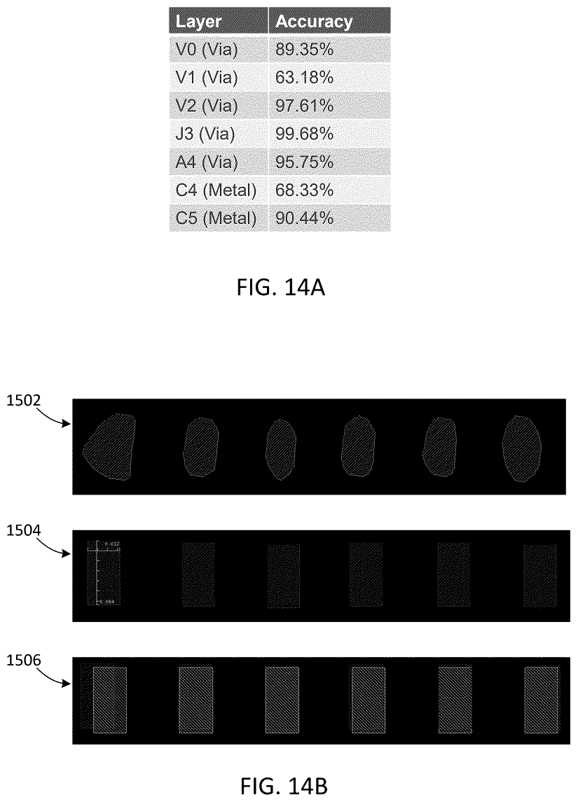

In one example DRC rectilinearization results, seven layers were corrected. FIG. 14A is a table of some of the result accuracies and FIG. 14B shows recovered versus corrected layouts for one example correction of seven layers in a recovered ASIC layout consistent with the present disclosure. The example of FIG. 14B shows a recovered layout 1502, a post-rectilinear (blue) and post-DRC correction (red) layout 1504, and a golden (yellow) and post DRC correction (red) layer 1506. The disclosed rectilinearization method achieved a 97% correction accuracy on the back end of line (BEOL) layers in a layout that contained 644,430 polygons. Without this new method, the accuracy was only 21%, which can cause major inaccurate results during V&V.

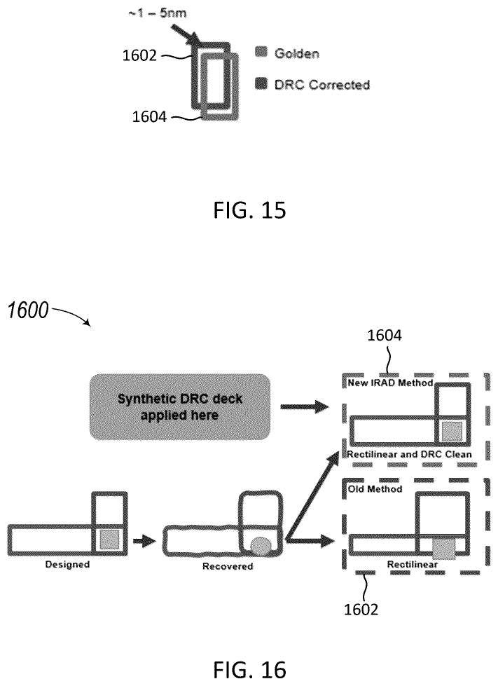

The accuracy is dependent on the quality of the SEM images. For example, FIG. 15 shows a very small offset between the golden layout 1504 and DRC corrected layout 1502 due to the nature of SEM images.

Consistent with the present disclosure there is thus provided a new rule-driven rectilinearization method that provides a recovered layout which better represents the golden layout. This highly increases the accuracy of certain V&V methods which allows for higher confidence in assurance metrics.

FIG. 16 is an example diagram of method 1600 for rule-driven rectilinearization of a recovered layout on the system of FIG. 1, consistent with the present disclosure. FIG. 16 diagrammatically illustrates results using a method consistent with the present disclosure vs. an old method as shown by the existing method results 1602 versus the disclosed method results 1604. The operations shown in FIG. 16 are described in FIG. 17.

FIG. 17 is a flowchart diagram depicting operations of process 1700 for design flow and obsolescence recovery through open-source tools and application of DRC rules on post-silicon layouts, on the system of FIG. 1, consistent with the present disclosure. It should be appreciated that embodiments of the present disclosure provide at least for rule-driven rectilinearization of a recovered layout. However, FIG. 17 provides only an illustration of one implementation and does not imply any limitations with regard to the environments in which different embodiments may be implemented. Many modifications to the depicted environment may be made by those skilled in the art without departing from the scope of the disclosure as recited by the claims.

Process 1700 includes receiving a design (operation 1702). In the illustrated example embodiment, the design to be analyzed is received by the system. The design to be analyzed may consist of layout files, such as HDL files from a PDK, images of extracted layers of an IC, and/or SEM images of the layers of the IC.

In an embodiment, the design to be analyzed may include a layout created by generating successive images of an integrated circuit, each of the successive images being associated with a different one of a plurality of layers of the integrated circuit and determining a layout of the integrated circuit in response to the successive images. This process takes advantage of the ASICs being built up using multiple layers for creating the circuits. An individual layer can be etched or delayered exposing the electrical connections hidden underneath. The exposed layer can be captured using imaging hardware before repeating the delayering process. Once all the layers have been accounted for, these images are used to recreate a GDSII file representing the layout of the original circuit.

In an embodiment, the design to be analyzed may be received as a golden GDSII file, and therefore no recovery of the GDSII file is required. In this embodiment, the process 1700 would then proceed to operation 1706.

Process 1700 includes recovering the design (operation 1704). In operation 1704, if the design to be analyzed was received as images of one or more layers of the IC, then process 1700 automates the design recovery by utilizing layout files and opensource tools. The HDL is synthesized into a gate level netlist. The circuit blocks used to achieve the functionality laid out by the HDL are dependent on standard cells for a given PDK. By knowing the PDK, the PDK provides a collection of cells to search for in a layout.

Device extraction is used to sift through layers of the layout to find circuit components such as transistors, resistors, capacitors, and so on. After determining the layers of the device, the next step is finding which layers in particular are necessary for extraction. After separating the device from the rest of the layout, its connections can begin to be formed.

Once a component is found, the nodes it is connected to can be traced through a user made connectivity list to form a netlist for each individual circuit component. The connectivity list specifies the path through layers a signal could take to get from one point to another. After repeating this for every device, a netlist is made for the whole circuit. With this netlist, the legacy circuit can be recreated.

Process 1700 includes creating a synthetic DRC deck (operation 1706). In operation 1706, process 1700 utilizes synthetic DRC rules derived from a golden layout (no PDK needed) or golden DRC rules from a PDK to guide the rectilinearization algorithm.

In an embodiment, the process 1700 may be used in cases where a PDK is not available, where a synthetic DRC deck can be resolved and then applied to the recovered layout. In cases where the PDK is available, the synthetic DRC deck will not have to be extracted and instead the original DRC deck can be applied directly. The process of improving recovered shapes using a DRC deck (synthetic or real) remains the same.

The process 1700 can create a synthetic DRC deck to assist with rectilinearization of the shapes on a recovered layout or use a provided DRC deck. By using a provided DRC deck, the accuracy of the other V&V techniques improves because the recovered shapes are not entirely dependent on the quality of the capture but instead are being assisted by a known set of design rules.

In the process of creating the synthetic DRC deck for manipulating the shapes in cases where the original DRC deck is not provided, the process 1700 also gathers PDK-specific information about the design. In these cases, although the real PDK that was used to create the design is initially unknown, by gathering information about the design to generate the synthetic DRC deck, the process 1700 may be able to map the design to the real PDK.

In addition, in the cases where the process 1700 is able to map the design to the real PDK instead of using the synthetic DRC deck, the process 1700 may have improved results on conforming shapes and therefore even better accuracy for the V&V. Also, knowing the PDK gives the process 1700 additional information about the design in general, such as the standard cells used in the PDK, and may assist the V&V process immensely.

Process 1700 includes applying the synthetic DRC deck to the recovered design (operation 1708). In operation 1708, process 1700 utilizes a golden or a synthetically derived DRC deck to flag and correct DRC violations during rectilinearization. In a traditional rectilinearization flow, DRC rules are not considered and therefore the resultant rectilinear layout does not closely represent the post fabricated layout. The process may utilize synthetic DRC rules derived in operation 1706 from a golden layout (no PDK needed) or golden DRC rules from a PDK to guide the rectilinearization algorithm. This produces a layout that closely represents a pre-fabrication layout but also preserving recovered layout artifacts.

Process 1700 includes generating a rectilinear and DRC clean design (operation 1710). In operation 1710, when performing rectilinearization the process 1700 attempts to remove all points that have some slope between them so that the result only contains perfectly horizontal or vertical lines. Some embodiments consistent with the present disclosure extend the rectilinearization algorithm and adds DRC checks to verify that the polygon it is creating does not violate DRC rules which may include, but are not limited to, polygon to polygon spacing, polygon width/length, and more. This significantly reduces the risk of manual error associated with known manual processes.

A DRC deck can thus be used to flag large imaging errors and assist in correction. A simple DRC deck is created and the rules are applied during rectilinearization. This allows a post-silicon layout to more closely represent a golden layout without losing the recovered artifacts.

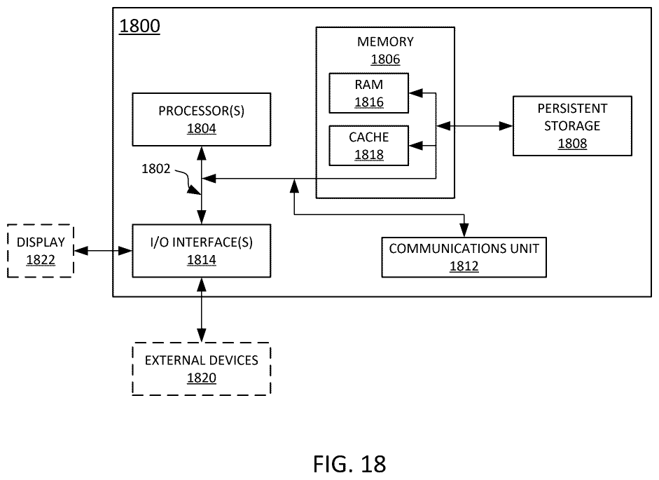

FIG. 18 is a block diagram depicting components of one example of the computing device 110 and/or computing device 132 executing the operations depicted in the flowchart of FIG. 17 and suitable for ASIC design flow and obsolescence recovery through open-source tools and application of DRC rules on post-silicon layouts, within the distributed data processing environment of FIG. 1, consistent with the present disclosure. FIG. 18 displays the computing device or computer 1800, one or more processor(s) 1804 (including one or more controllers or computer processors), a communications fabric 1802, a memory 1806 including, a random-access memory (RAM) 1816 and a cache 1818, a persistent storage 1808, a communications unit 1812, I/O interfaces 1814, a display 1822, and external devices 1820. It should be appreciated that FIG. 18 provides only an illustration of one embodiment and does not imply any limitations with regard to the environments in which different embodiments may be implemented. Many modifications to the depicted environment may be made.

As depicted, the computer 1800 operates over the communications fabric 1802, which provides communications between the computer processor(s) 1804, memory 1806, persistent storage 1808, communications unit 1812, and input/output (I/O) interface(s) 1814. The communications fabric 1802 may be implemented with an architecture suitable for passing data or control information between the processors 1804 (e.g., microprocessors, communications processors, and network processors), the memory 1806, the external devices 1820, and any other hardware components within a system. For example, the communications fabric 1802 may be implemented with one or more buses.

The memory 1806 and persistent storage 1808 are computer readable storage media. In the depicted embodiment, the memory 1806 comprises a RAM 1816 and a cache 1818. In general, the memory 1806 can include any suitable volatile or non-volatile computer readable storage media. Cache 1818 is a fast memory that enhances the performance of processor(s) 1804 by holding recently accessed data, and near recently accessed data, from RAM 1816.

Program instructions for ASIC design flow and obsolescence recovery through open-source tools and application of DRC rules on post-silicon layouts may be stored in the persistent storage 1808, or more generally, any non-transitory computer readable storage media, for execution by one or more of the respective computer processors 1804 via one or more memories of the memory 1806. The persistent storage 1808 may be a magnetic hard disk drive, a solid-state disk drive, a semiconductor storage device, flash memory, read only memory (ROM), electronically erasable programmable read-only memory (EEPROM), or any other computer readable storage media that is capable of storing program instruction or digital information.

The media used by persistent storage 1808 may also be removable. For example, a removable hard drive may be used for persistent storage 1808. Other examples include optical and magnetic disks, thumb drives, and smart cards that are inserted into a drive for transfer onto another computer readable storage medium that is also part of persistent storage 1808.

The communications unit 1812, in these examples, provides for communications with other data processing systems or devices. In these examples, the communications unit 1812 includes one or more network interface cards. The communications unit 1812 may provide communications through the use of either or both physical and wireless communications links. In the context of some embodiments of the present disclosure, the source of the various input data may be physically remote to the computer 1800 such that the input data may be received, and the output similarly transmitted via the communications unit 1812.

The I/O interface(s) 1814 allows for input and output of data with other devices that may be connected to computer 1800. For example, the I/O interface(s) 1814 may provide a connection to external device(s) 1820 such as a keyboard, a keypad, a touch screen, a microphone, a digital camera, and/or some other suitable input device. External device(s) 1820 can also include portable computer readable storage media such as, for example, thumb drives, portable optical or magnetic disks, and memory cards. Software and data used to practice embodiments of the present disclosure can be stored on such portable computer readable storage media and can be loaded onto persistent storage 1808 via the I/O interface(s) 1814.

I/O interface(s) 1814 may also connect to a display 1822. Display 1822 provides a mechanism to display data to a user and may be, for example, a computer monitor. Display 1822 can also function as a touchscreen, such as a display of a tablet computer.

According to one aspect of the disclosure, there is provided a method of generating a DRC clean design, the method including: generating successive images of an integrated circuit, each of the successive images being associated with a different one of a plurality of layers of the integrated circuit; determining a layout of the integrated circuit in response to the successive images; collecting at least one measurement of at least one feature in the layout; and modifying the layout in response to the at least one measurement.

According to another aspect of the disclosure, there is provided a method of correcting design rule violations during rectilinearization, the method including: receiving a recovered layout of an integrated circuit; recovering a design from the recovered layout of the integrated circuit; deriving one or more design rules from the recovered layout of the integrated circuit; and rectilinearizing the recovered layout in response to the one or more design rules to create a rectilinear and clean design.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems. The term “coupled” as used herein refers to any connection, coupling, link, or the like by which signals carried by one system element are imparted to the “coupled” element. Such “coupled” devices, or signals and devices, are not necessarily directly connected to one another and may be separated by intermediate components or devices that may manipulate or modify such signals. Likewise, the terms “connected” or “coupled” as used herein in regard to mechanical or physical connections or couplings is a relative term and does not require a direct physical connection. Elements, components, modules, and/or parts thereof that are described and/or otherwise portrayed through the figures to communicate with, be associated with, and/or be based on, something else, may be understood to so communicate, be associated with, and/or be based on in a direct and/or indirect manner, unless otherwise stipulated herein.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements. The phrase “at least one of A and B” should be understood to mean “only A, only B, or both A and B.”

Spatially relative terms, such as “beneath,” below,” upper,” “lower,” “above,” “left,” “right” and the like may be used herein for ease of description to describe one element or feature's relationship to another element(s) or feature(s) as illustrated in the drawings. These spatially relative terms are intended to encompass different orientations of the device in use or operation in addition to the orientation shown in the drawings. For example, if the device in the drawings is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

Although the terms “first,” “second,” “third” etc. may be used to describe various elements, components, regions, layers and/or sections, these elements, components, regions, layers, and/or sections are not to be limited by these terms as they are used only to distinguish one element, component, region, layer or section from another element, component, region, layer, or section. Thus, a first element, component, region, layer, or section could be termed a second element, component, region, layer, or section without departing from the scope and teachings of the present invention.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

The programs described herein are identified based upon the application for which they are implemented in a specific embodiment of the disclosure. However, it should be appreciated that any particular program nomenclature herein is used merely for convenience, and thus the disclosure should not be limited to use solely in any specific application identified and/or implied by such nomenclature.

The present disclosure may be a system, a method, and/or a computer program product. The system or computer program product may include one or more non-transitory computer readable storage media having computer readable program instructions thereon for causing a processor to carry out aspects of the present disclosure.

The one or more non-transitory computer readable storage media can be any tangible device that can retain and store instructions for use by an instruction execution device. The one or more non-transitory computer readable storage media may be, for example, but is not limited to, an electronic storage device, a magnetic storage device, an optical storage device, an electromagnetic storage device, a semiconductor storage device, or any suitable combination of the foregoing. A non-transitory computer readable storage media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from one or more non-transitory computer readable storage media or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in one or more non-transitory computer readable storage media within the respective computing/processing device.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some embodiments, electronic circuitry including, for example, programmable logic circuitry, Field-Programmable Gate Arrays (FPGA), or other Programmable Logic Devices (PLD) may execute the computer readable program instructions by utilizing state information of the computer readable program instructions to personalize the electronic circuitry, in order to perform aspects of the present disclosure.

It will be appreciated by those skilled in the art that any block diagrams herein represent conceptual views of illustrative circuitry embodying the principles of the disclosure. Similarly, it will be appreciated that any block diagrams, flow charts, flow diagrams, state transition diagrams, pseudocode, and the like represent various processes which may be substantially represented in computer readable medium and so executed by a computer or processor, whether or not such computer or processor is explicitly shown. Software modules, or simply modules which are implied to be software, may be represented herein as any combination of flowchart elements or other elements indicating performance of process steps and/or textual description. Such modules may be executed by hardware that is expressly or implicitly shown.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method for generating a DRC clean design, the method comprising:
generating successive images of an integrated circuit, each of the successive images being associated with a different one of a plurality of layers of the integrated circuit;
determining a layout of the integrated circuit in response to the successive images;
collecting at least one measurement of at least one feature in the layout; and
modifying the layout in response to the at least one measurement.

2. The method of claim 1, wherein generating the successive images of the integrated circuit, each of the successive images being associated with the different one of the plurality of layers of the integrated circuit further comprises:
for each layer of the plurality of layers of the integrated circuit:
exposing an individual layer of the integrated circuit, wherein the individual layer of the integrated circuit is exposed using at least one of etching or delayering; and
capturing the exposed layer using imaging hardware.

3. The method of claim 2, wherein the imaging hardware is a scanning electron microscope (SEM).

4. The method of claim 1, wherein determining the layout of the integrated circuit in response to the successive images further comprises:
extracting devices from each layer of the plurality of layers of the integrated circuit;
creating a connectivity list from each of the extracted devices; and
creating a netlist for the integrated circuit from the connectivity list for each of the extracted devices.

5. The method of claim 4, wherein the connectivity list specifies a path through any layer of the plurality of layers that a signal could take to get from one point in the layout to another point in the layout.

6. The method of claim 4, wherein the netlist for the integrated circuit represents an original design of the integrated circuit.

7. The method of claim 1, wherein collecting the at least one measurement of the at least one feature in the layout further comprises:
collecting a specific measurement between each specific shape across each layer of the plurality of layers; and
normalizing a minimum dimension of the collected specific measurements between each specific shape across the each layer of the plurality of layers to determine a design rule.

8. The method of claim 7, wherein modifying the layout in response to the at least one measurement further comprises:
detecting any design rule violations in the layout; and
correcting the design rule violations in the layout.

9. The method of claim 8, wherein correcting the design rule violations in the layout further comprises:
applying the design rule to correct one or more misshapen shapes from the layout; and
applying the design rule to correct one or more unaligned shapes from the layout.

10. A method for correcting design rule violations during rectilinearization, the method comprising:
receiving a recovered layout of an integrated circuit;
recovering a design from the recovered layout of the integrated circuit;
deriving one or more design rules from the recovered layout of the integrated circuit; and
rectilinearizing the recovered layout in response to the one or more design rules to create a rectilinear and clean design.

11. The method of claim 10, wherein the recovered layout comprises images of extracted layers of the integrated circuit.

12. The method of claim 10, wherein recovering the design from the recovered layout of the integrated circuit further comprises:
extracting devices from each layer of a plurality of layers of the integrated circuit;
creating a connectivity list from each of the extracted devices; and
creating a netlist for the integrated circuit from the connectivity list for each of the extracted devices.

13. The method of claim 12, wherein the connectivity list specifies a path through any layer of the plurality of layers that a signal could take to get from one point in the recovered layout to another point in the recovered layout.

14. The method of claim 12, wherein the netlist for the integrated circuit represents an original design of the integrated circuit.

15. The method of claim 10, wherein deriving the one or more design rules from the recovered layout of the integrated circuit further comprises:
collecting a specific measurement between each specific shape across each layer of the plurality of layers; and
normalizing a minimum dimension of the collected specific measurements between each specific shape across the each layer of the plurality of layers to determine a new design rule of the one or more design rules.

16. The method of claim 10, wherein rectilinearizing the recovered layout in response to the one or more design rules to create the rectilinear and clean design further comprises:
detecting any design rule violations in the recovered layout;
correcting the design rule violations in the recovered layout; and
rectilinearizing the recovered layout.

17. The method of claim 16, wherein correcting the design rule violations in the recovered layout further comprises:
applying the one or more design rules to correct one or more misshapen shapes from the recovered layout; and
applying the one or more design rules to correct one or more unaligned shapes from the recovered layout.

18. The method of claim 10, further comprising:
recovering an original circuit schematic of the integrated circuit for obsolescence recovery from the rectilinear and clean design.

19. The method of claim 14, further comprising:
comparing the rectilinear and clean design to the original design; and
determining whether the integrated circuit has been tampered with based on a results of the comparison.

20. The method of claim 10, wherein the one or more design rules are derived from a golden layout.
